(19) United States
(12) Patent Application Publication
(10) Pub. No.: US 2013/0264559 A1
(43) Pub. Date: Oct. 10, 2013

(54) Hole Injection Layers

(71) Applicants: Thomas Kugler, Milton (GB); Richard Wilson, Girton (GB)

(72) Inventors: Thomas Kugler, Milton (GB); Richard Wilson, Girton (GB)

(73) Assignee: CAMBRIDGE DISPLAY TECHNOLOGY LIMITED, Cambridgeshire (GB)

(21) Appl. No.: 13/992,226

(22) PCT Filed: Dec. 1, 2011
(86) PCT No.: PCT/GB2011/001668

§ 371 Date: Jun. 6, 2013

(30) Foreign Application Priority Data
Dec. 6, 2010 (GB) 1020617.5

(51) Int. Cl. H01L 51/00

(52) U.S. Cl. CPC H01L 51/0022
USPC 257/40; 438/46

(57) ABSTRACT

The present invention provides a process for the preparation of a device comprising a transition metal oxide doped interface between an anode and a semiconducting hole transport layer, comprising the steps of depositing a solution comprising a precursor for a metal oxide layer on said anode, drying and optionally annealing the deposited solution to form a solid layer precursor, depositing a solution of said semiconducting hole transport layer material onto the solid layer, and optionally annealing thermally the resulting product to give the desired device having transition metal oxide at the interface between said anode and said semiconducting hole transport layer; together with a device obtainable by the process according to the invention.

### FIELD OF INVENTION

The present invention provides a solution-based process for creating hole injection layers (HILs) based on transition metal oxide (e.g. molybdenum trioxide)-doped interfaces between the anode contact and semiconducting hole transport layers (HTLs) in electronic devices comprising conjugated molecules or polymers such as organic light emitting diodes (OLEDs), organic thin film transistors (OTFTs) and organic photovoltaic cells (OPVs).

Due to their strong electron accepting properties, suitable transition metal oxides such as molybdenum trioxide enable the formation of ohmic contacts and efficient hole injection even in the case of HTLs with high ionisation potentials (i.e. deep HOMO levels), as required for organic light emitting diode (OLED) pixels with deep-blue emitters.

### BACKGROUND OF THE INVENTION

There has been considerable interest in light emitting organic materials such as conjugated polymers for a number of years. Light emitting polymers possess a delocalised pi-electron system along the polymer backbone. The delocalised pi-electron system confers semiconducting properties to the polymer and gives it the ability to support positive and negative charge carriers with high mobilities along the polymer chain.

Thin films of these conjugated polymers can be used in the preparation of optical devices such as light-emitting devices. These devices have numerous advantages over devices prepared using conventional semiconducting materials, including the possibility of wide area displays, low DC working voltages and simplicity of manufacture. Devices of this type are described in, for example, WO-A-90/13148, U.S. Pat. No. 5,512,654 and WO-A-95/06400.

Great efforts have been dedicated to the realization of a full-colour, all plastic screen. The major challenges to achieve this goal are: (1) access to conjugated polymers emitting light of the three basic colours red, green and blue; and (2) the conjugated polymers must be easy to process and fabricate into full-colour display structures. OLEDs are effective in meeting the first requirement, since manipulation of the emission colour can be achieved by changing the chemical structure of the organic emissive compound.

However, while modulation of the chemical nature of the emissive layer is often relatively easy and inexpensive on the lab scale it can be an expensive and complicated process on the industrial scale. The second requirement of the easy processability and build-up of full colour matrix devices raises the question of how to micro-pattern fine multicolour pixels and how to achieve full-colour emission. Inkjet printing, hybrid inkjet printing technology and spin coating are examples of suitable technologies that can be adopted to apply the polymer solutions in the desired pattern.

At their most basic, organic electroluminescent devices generally comprise an organic light emitting material which is positioned between a hole injecting electrode and an electron injecting electrode. The hole injecting electrode (anode) is typically a transparent tin-doped indium oxide (ITO)-coated glass substrate. The material commonly used for the electron injecting electrode (cathode) is a low work function metal such as calcium or aluminium.

The materials that are commonly used for the organic light emitting layer include conjugated polymers such as poly-phenylene-vinylene (PPV) and derivatives thereof (see, for example, WO-A-90/13148), polyfluorene derivatives (see, for example, A. W. Grice, D. D. C. Bradley, M. T. Bernius, M. Inbasekaran, W. W. Wu, and E. P. Woo, Appl. Phys. Lett. 1998, 73, 629, WO-A-00/55927 and Bernius et al., Adv. Materials, 2000, 12, No. 23, 1737), polynaphthylene derivatives and polyphenanthrenyl derivatives; and small organic molecules such as aluminium quinolinol complexes (Alq3 complexes: see, for example U.S. Pat. No. 4,539,507) and quinacridone, rubrene and styryl dyes (see, for example, JP-A-264692/1988). The organic light emitting layer can comprise mixtures or discrete layers of two or more different emissive organic materials.

Typical device architecture is disclosed in, for example, WO-A-90/13148; U.S. Pat. No. 5,512,654; WO-A-95/06400; R. F. Service, Science 1998, 279, 1135; Wudl et al., Appl. Phys. Lett. 1998, 73, 2561; J. Bharathan, Y. Yang, Appl. Phys. Lett. 1998, 72, 2660; T. R. Hebner, C. C. Wu, D. Marcy, M. L. Lu, J. Sturm, Appl. Phys. Lett. 1998, 72, 519); and WO 99/48160.

The injection of holes from the hole injecting layer such as ITO into the organic emissive layer is controlled by the energy difference between the hole injecting layer work function and the highest occupied molecular orbital (HOMO) of the emissive material, and the chemical interaction at the interface between the hole injecting layer and the emissive material. The deposition of high work function organic materials on the hole injecting layer, such as poly (styrene sulfonate)-doped poly (3,4-ethylene dioxythiophene) (PEDOT/PSS), N,N′-diphenyl-N,N′-(2-naphthyl)-(1,1′-phenyl)-4,4′-diamine (NBP) and N,N′-bis(3-methylphenyl)-1,1′-biphenyl-4,4′-diamine (TPD), provides hole transport layers (HTLs) which facilitate the hole injection into the light emitting layer, transport holes stably from the hole injecting electrode and obstruct electrons. These layers are effective in increasing the number of holes introduced into the light emitting layer. However, the surface of ITO is not well defined and the chemistry at the interface with these conventional hole transport materials is hard to control.

As an alternative to the high work function organic materials such as PEDOT/PSS, high resistivity inorganic layers have been proposed for use as hole transport layers in, for example, EP-A-1009045, EP-A-1022789, EP-A-1030539 and EP-A-1041654. EP-A-1022789 discloses an inorganic hole transport layer which is capable of blocking electrons and has conduction paths for holes. The layer has a high resistivity, stated to be preferably in the region of 103 to 108 Ω·cm. The materials which are disclosed have the general formula (Si₁₋ₓGeₓ)O_{y} wherein 0≦x≦1 and 1.7≦y≦2.2. The work function of this hole transport layer is not well defined and is likely to vary depending upon the actual identity of x and y.

More recently, Chen et al, Applied Physics Letters 87, 241121 (2005) has disclosed a connecting structure for tandem organic light-emitting devices. The connecting structure consists of a thin metal layer as the common electrode, a hole-injection layer (HIL) containing molybdenum trioxide on one side of the common electrode, and an electron-injection layer involving Cs₂CO₃ on the other side. Such a connecting structure permits opposite hole and electron injection into two adjacent emitting units and gives tandem devices superior electrical and optical performances. The structure is prepared wholly by thermal evaporation.

Kanai et al, Organic Electronics 11, 188-194 (2010) discloses that an electronic structure at the α-NPD/MoO₃/Au interfaces has been investigated (molybdenum trioxide deposied by thermal evaporation). It was found that the molybdenum trioxide layer contains a number of oxygen vacancies prior to any treatment and gap states are induced by the partial filling of the unoccupied 4d orbitals of molybdenum atoms neighbouring oxygen vacancies. The α-NPD thickness dependence of XPS spectra for the α-NPD/MoO₃ system clearly showed that molybdenum atoms at the surface of the molybdenum trioxide film were reduced by α-NPD deposition through the charge-transfer interaction between the adsorbed α-NPD and the molybdenum atoms. This reduction at the α-NPD/MoO₃ interface formed a large interface dipole layer. The deduced energy-level diagram for the α-NPD/MoO₃/Au interfaces describes the energy-level matching that explains well the significant reduction in the hole-injection barrier due to the molybdenum trioxide buffer layer.

Bolink et al, Adv. Funct. Mater. 18, 145-150 (2008) discloses a form of bottom-emission electroluminescent device in which a metal oxide is used as the electron-injecting contact. The preparation of the device comprises thermal deposition of a thin layer of a metal oxide on top of an indium tin oxide covered glass substrate, followed by the solution processing of the light-emitting layer and subsequently the deposition of a high-workfunction (air-stable) metal anode. The authors showed that the device only operated after the insertion of an additional hole-injection layer in between the light-emitting polymer (LEP) and the metal anode.

In summary, the prior art describes the use of thermally evaporated molybdenum trioxide as either hole injecting layers, or as electron injecting layers. However, while the use of molybdenum trioxide and potentially other transition metal oxides as a hole injecting layer to dope the interface between an anode and a semiconducting hole transport layer improves the efficiency of injection of holes from the hole injecting anode to the semiconducting layer, the thermal evaporation techniques used to deposit the HILs are not ideal for scaling up for use on a manufacturing scale.

There is therefore a need for an improved process for the preparation of a device such as an OLED, an OTFT or an OPV comprising a transition metal oxide dopedinterface acting as a hole injection layer between an anode and a semiconducting hole transport layer. The present invention addresses this need.

### SUMMARY OF THE INVENTION

The present invention provides an improved process for the preparation of a device such as an OLED, an OTFT or an OPV comprising a transition metal oxide dopedinterface acting as a hole injection layer between an anode and a semiconducting hole transport layer by means of a solution-based process for depositing transition metal oxides onto the anode in a device.

Thus, in a first aspect of the present invention there is provided:

(1) a process for the preparation of a device comprising a transition metal oxide doped interface between an anode and a semiconducting hole transport layer, comprising the following steps:
(a) depositing a solution comprising a precursor for a metal oxide layer on said anode;
(b) drying and optionally annealing the deposited solution to form a solid layer precursor;
(c) depositing a solution of said semiconducting hole transport layer material onto the solid layer; and
(d) optionally annealing thermally the product of step (c) to give the desired device having transition metal oxide at the interface between said anode and said semiconducting hole transport layer.

We have discovered that solution-based processing of transition metal oxides such as molybdenum trioxide in the process of the present invention enables the use of simple and cost-effective solution deposition techniques such as spin-coating, dip-coating or doctor-blading. In contrast to thermal evaporation, solution-based deposition techniques do not require vacuum, and can therefore easily be scaled-up to large substrate sizes and/or reel-to-reel fabrication processes.

Preferred embodiments according to the first aspect of the invention include:

(2) the process according to (1) wherein the transition metal oxide is an oxide of molybdenum, tungsten, or vanadium;

(3) the process according to (2), wherein the transition metal oxide is selected from the group consisting of molybdenum trioxide, tungsten trioxide and vanadium pentoxide;

(4) the process according to (3), wherein the precursor for molybdenum trioxide is a dispersion or a dissolution of molybdenum trioxide, molybdic acid, ammonium molybdate or phosphomolybdic acid in water;

(5) the process according to (3) wherein the precursor for molybdenum trioxide is a dispersion or a dissolution of phosphomolybdic acid in a polar organic solvent;

(6) the process according to (3), wherein the precursor for tungsten trioxide is a dispersion or a dissolution of tungsten trioxide, tungstic acid, ammonium tungstate or phosphotungstic acid in water;

(7) the process according to (3) wherein the precursor for tungsten trioxide is a dispersion or a dissolution of phosphotungstic acid in a polar organic solvent;

(8) the process according to (3), wherein the precursor for vanadium pentoxide is a dispersion or a dissolution of vanadium (V) oxide, ammonium metavanadate, vanadium(V) oxytriethoxide, vanadium(V) oxytriisopropoxide or vanadium(V) oxytripropoxide in water;

(9) the process according to (3) wherein the precursor for vanadium pentoxide is a dispersion or a dissolution of vanadium(V) oxytriethoxide, vanadium(V) oxytriisopropoxide or vanadium(V) oxytripropoxide in a polar organic solvent;

(10) the process according to any one of (1) to (9), wherein the precursor formulation in step (a) is deposited by spin-coating, dip-coating or doctor-blading;

(11) the process according to any one of (1) to (10), wherein the anode comprises indium tin oxide;

(12) the process according to any one of (1) to (11) in which the anode surface is pre-treated with a hot mixture of concentrated hydrogen peroxide and concentrated ammonium hydroxide, by UV-ozone treatment or oxygen plasma treatment before deposition of the solution comprising a precursor for a metal oxide;

(13) the process according to any one of (1) to (12) for the production of an organic light emitting device, wherein thermal cross-linkers are included in the semiconducting hole transport layer material deposited in step (c) and the product of step (c) is thermally annealed in step (d);

(14) the process according to (13) wherein a solution of a semiconducting light emitting polymer material is deposited onto the annealed semiconducting hole transport layer and the deposited solution is then dried to form a solid semiconducting light emitting polymer layer;

(15) the process according to any one of (1) to (14), wherein the annealing step (d) is conducted at a temperature range of from 200 to 300° C.; and

(16) the process according to any one of (1) to (15), wherein after step (d) a second solution of a semiconducting hole transport layer material, which may be the same or different from the first semiconducting hole transport layer material is deposited onto the annealed semiconducting hole transport layer and the deposited solution dried to form a non-annealed second layer of said semiconducting hole transport layer material.

In a second aspect of the present invention, there is provided a device comprising a transition metal oxide doped interface between an anode and a semiconducting hole transport layer obtained by the process of the present invention. Thus, in a second aspect there is provided:

(17) a device comprising a transition metal oxide doped interface between an anode and a semiconducting hole transport layer, wherein said device is produced according to a process according to any one of (1) to (16) above; and

(18) the device according to (17), wherein said device is selected from organic light emitting devices, organic photovoltaic cells and organic thin film transistors.

### DETAILED DESCRIPTION OF THE INVENTION

Solution-based processing of transition metal oxides such as molybdenum trioxide according to the process of the present invention enables the use of simple and cost-effective deposition techniques such as spin-coating, dip-coating or doctor-blading. In contrast to thermal evaporation, solution-based deposition techniques do not require vacuum, and can therefore easily be scaled-up to large substrate sizes and/or reel-to-reel fabrication processes. This is a substantial advantage as it enables manufacturing-scale process solutions to be achieved for the desired device architecture in which the devices comprise a transition metal oxide doped interface between an anode and a semiconducting hole transport layer, something that has not previously been readily achievable. Additionally, a further advantage of solution-processed transition metal oxides such as molybdenum trioxide in accordance with the present invention is the elimination of lateral leakage currents.

In its broadest form, the invention comprises the following process steps for realising p-doped interfaces between the indium tin oxide (ITO) anode and hole transport layers (HTLs) in devices such as OLEDs:
(i) formulation of a solution of a precursor for the transition metal oxide (water- or organic solvent-based);
(ii) deposition of the solution of the precursor for the transition metal oxide onto the anode surface;
(iii) a solution of a hole transport layer material (e.g. inter-layer polymer, pendant polymer, conjugated host material or organic semiconductor material) is spin-coated onto the anode contacts modified by deposition thereon of the precursor for the transition metal oxide; and
(iv) thermal annealing of the product of (iii) results in p-doping of the interface between the hole transport layer material and the anode contact, which enables efficient injection of holes from the anode into the hole transport layer material.

As noted above, preferably the transition metal oxide is an oxide of molybdenum, tungsten or vanadium, more preferably an oxide of molybdenum. Preferred transition metal oxides are selected from the group consisting of molybdenum trioxide, tungsten trioxide and vanadium pentoxide, most preferably molybdenum trioxide.

The molybdenum trioxide precursor solution can be water-based or organic solvent-based.
Water-based formulations of molybdenum trioxide precursors involve the dispersion and/or dissolution of water-soluble precursor materials such as molybdenum trioxide, molybdic acid or phosphomolybdic acid in water.
An example of an organic solvent-based solution is phosphomolybdic acid dissolved in pyridine, acetonitrile, tetrahydrofurane or other polar organic solvents.

Using molybdenum as an example of the transition metal oxide for use in the in invention, a common feature in solutions of molybdenum trioxide precursors is the presence of strong Lewis acid-Lewis base interactions between the molybdenum (VI) compounds and electron lone pairs of the solvent molecules.

In the case of molybdenum trioxide dispersions in water, this results in a number of complex chemical interactions between the precursor material and the water molecules:
Molybdenum (VI) oxide is slightly soluble in water and reacts to form molybdic Acid:

MoO₃+H₂O→H₂MoO₄.
As a function of pH value, Molybdic Acid poly-condenses to form a wide range of polyanionic species such as:

7 MoO₄²⁻+8H⁺→Mo₇O₂₄⁶⁻+4H₂O

or

MoO₈O₂₆⁴⁻, Mo₃₆O₁₁₂(H₂O)₁₆⁸⁻.

As a consequence of these chemical interactions, the pH of the resulting solution determines both the saturation concentration of dissolved molybdenum trioxide (“molybdic acid”) and the structural properties of the resulting (polycondensed) molybdic acid species.

Solution-processed molybdenum trioxide has potential applications for reducing contact resistance in a range of organic electronic devices, including organic light emitting diodes (OLEDs), organic photovoltaic cells (OPVs), and organic thin film transistors (OTFTs).

To fabricate OLEDs with a transition metal oxide-based hole injection layer (HIL), the transition metal oxide precursor formulation can be spin-coated onto the ITO anode patterns on the OLED substrate. Alternative deposition techniques include dip-coating and doctor-blading, although any suitable solution deposition technique can be used.

The deposition process comprises several steps, which are detailed in the following, using molybdenum trioxide as an example:

In the case of water-based molybdenum trioxide precursor solutions, it is important that the ITO surface is highly hydrophilic, in order to ensure perfect wettability. This can be achieved by applying oxidative surface pre-treatments prior to depositing the water-based molybdenum trioxide precursor solution. Examples of such oxidative surface treatments include:

Immersion in a hot mixture of concentrated hydrogen peroxide and concentrated ammonium hydroxide (“Piranha solution”)

UV-Ozone Treatments

Oxygen Plasma Treatments.

After the oxidative surface pre-treatment, the substrates are rinsed with de-ionised water to remove any water-soluble contaminants.

The molybdenum trioxide precursor solution is then applied to the OLED substrate, e.g. by spin-coating.

After spin-coating the molybdenum trioxide precursor, the OLED substrates are dried and then annealed (“pre-Interlayer bake”).

A variety of drying procedures can be used, including drying in air, under an inert gas (i.e. in a glove box), or under nitrogen.

Drying temperatures typically range from 100° C. to 150° C., and the drying times typically range from several minutes to several hours. Annealing temperatures typically range from 180° C. to 300° C., and the drying times typically range from several minutes to several hours.

The condition of the resulting modified ITO surface depends on the molybdenum trioxide precursor solution, and the deposition, drying and annealing parameters:

Using the transition metal oxide precursor solutions and the deposition parameters of the invention, the thickness of the resulting transition metal oxide deposit on ITO is typically less than 1 nm (AFM surface roughness data).

In addition to ITO, other transparent conductive oxides (TCOs), and also metals can be coated with solution-processed transition metal oxides such as molybdenum trioxide to create low-contact resistance contacts.

We should note that the precise make up of the transition metal oxide deposited on the ITO surface will depend upon a number of factors, chiefly the identity of the precursor solution and the temperature at which annealing takes place. For example, while deposition of an aqueous solution of molybdic acid followed by annealing provides essentially pure molybdenum trioxide, annealing of phosphomolybdic acid is believed to result in the formation of molybdenum trioxide containing minor amounts of phosphorous pentoxide. Transition metal oxides that contain minor amounts of other compounds formed during the transition from the precursor to said oxide are still generally suitable for use in the process of the present invention and are encompassed within the scope of the definition of “transition metal oxides”.

In the case of gold source and drain contacts for organic thin film transistors, the gold surface should preferably be pre-treated with an ammonium thio-transition metal complex such as ammonium tetrathiomolybdate, to enable good adhesion between the transition metal oxide and the gold. This process typically involves comprises:

(a) pre-treating the metal surface with an ammonium thio-transition metal complex;

(b) depositing (e.g. spin-coating, dip-coating or inkjet-printing) a solution comprising transition metal oxide precursor onto the pre-treated surface; and

(c) annealing the deposited solution to form a layer of transition metal oxide.

After the “pre-Interlayer bake” step, a Hole Transport Layer (HTL) is spin-coated onto the transition metal oxide-modified ITO contacts. Possible HTL materials include interlayers (e.g. Interlayers 1, 2 and 3—see below), pendant polymers (e.g. see discussion below) and light emitting polymers (e.g. LEP 1—see below).

For OLED applications, an important pre-requisite is the provision of thermal cross-linkers in the first HTL layer. This allows the first HTL layer to be rendered insoluble by thermal annealing, prior to spin-coating a second light emitting polymer layer on top of the HTL layer, without re-dissolving the first HTL layer. For example, interlayer 3 contains 7.5% of the cross linker BCB.

### LEP1

### Dibromide—44% MONOMER 1, 6% MONOMER 2

### Diester—36% MONOMER 3, 14% F8

### Interlayer 1

### Dibromide—40% MONOMER 1, 5% BCBF, 5% MONOMER 4

### Diester—35% MONOMER 5, 14% F8

### Interlayer 2

### Dibromide—30% MONOMER 6, 12.5% F8, 7.5% BCBF

### Diester—50% MONOMER 7

### Interlayer 3

### Dibromide—30% MONOMER 8, 12.5% F8, 7.5% BCBF

### Diester—50% MONOMER 7

F8 (Dibromide)—(for Synthesis See U.S. Pat. No. 6,593,450)

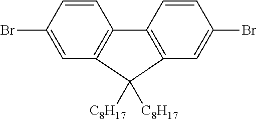

### Monomer 7 (Diester)—

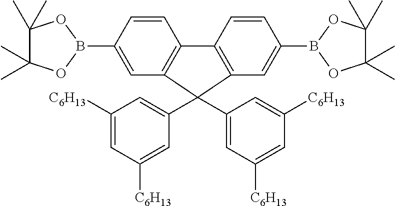

(for synthesis see WO2006/109083, WO2009/066061)

### BCBF (Dibromide)—

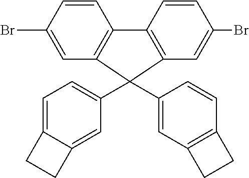 [SMILES: Brc1ccc2c(c1)C(c1ccc3c(c1)CC3)(c1ccc3c(c1)CC3)c1cc(Br)ccc1-2]

(for synthesis see WO2008/038747)

### Monomer 5 (Diester)—

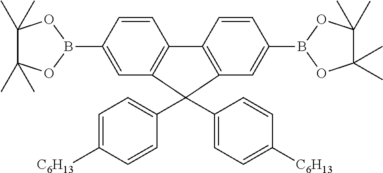

(for synthesis see WO2002/092723)

### Monomer 3 (Diester)—

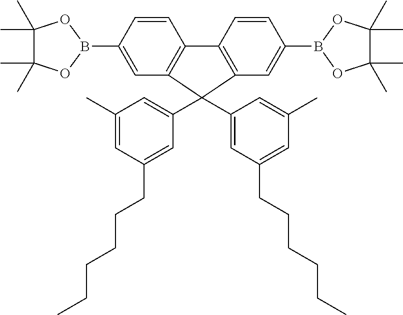

(for synthesis see WO2009/066061)

### Monomer 1 (Dibromide)—

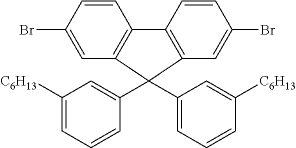

(for synthesis see WO2009/066061)

### Monomer 2—

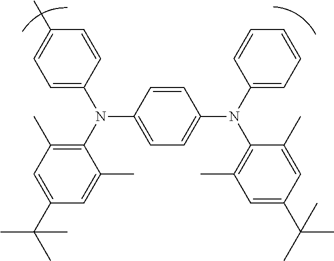 [SMILES: Cc1ccc(N(c2ccc(N(c3ccccc3)c3c(C)cc(C(C)(C)C)cc3C)cc2)c2c(C)cc(C(C)(C)C)cc2C)cc1]

(for synthesis see WO2008/016090, WO2008/111658, WO2009/110642, WO2010/013724.)

### Monomer 6 (Dibromide)—

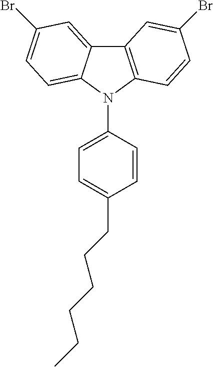 [SMILES: CCCCCCc1ccc(-n2c3ccc(Br)cc3c3cc(Br)ccc32)cc1]

(for synthesis see WO2006/096399, WO2010/013723)

### Monomer 8—

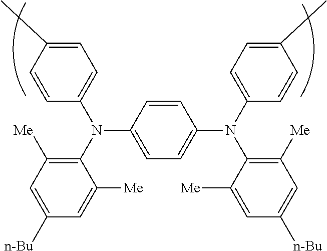

(for synthesis see WO2005/074329, WO2006/123741)

### Monomer 4—

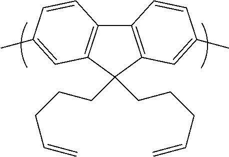

(for synthesis see WO2010/013723, WO2010/013724)

Turning to suitable pendant polymers for use in the present invention, PPV derivatives with carbazole pendants are described in J. Mater. Chem., 2001, 11, 3023-3030 where single layer devices are described (ITO/organic/Al). Prof Jen has published papers on polystyrene based hole transport pendant polymers cross linked on top of ITO//PEDOT in Adv. Mater. 2009, 21, 1972-1975 and J. Mat. Chem., 2008 (18) p. 4459. Photo-cross linkable hole conducting polymers are discussed in Macromolecules 2005, 38, 1640-1647. Polyfluorene-based pendant polymers have been published in Macromolecules, 2009, 42, 4053-4062.

The use of pendant polymers in organic electronic devices is known in the literature. For example, several patents by Thomson describe the use of pendant polymers as active layers in OLED device:

### EP0712171A1, EP0850960A1, EP0851017A1, FR2736061A1, FR2785615A1, WO0002936A1 and WO9965961A1.

In these patents, various hole-transport and electron-transport units are used as active pendant groups (for instance naphtylimide, carbazole, pyrazoline, benzoxazol, benzothiazole, anthracene and phenanthrene). The backbones are typically polyacrylate, polystyrene or polyethylene. Cross-linking units are also incorporated in the materials to allow subsequent depositions of layers. The cross-linking process can be initiated thermally or photo-induced.

Additional references describing the preparation and use of polymers with pendant active units are given below; in these cases, no cross-linker units are used:
J. Mat. Chem., 2007, 17, 4122-4135, where TTF derivatives are used as pendant groups for electron-donating polymers.
J. Mat. Chem., 1993, 3(1), 113-114: polymers containing pendant oligothiophenes as a novel class of electrochromic materials
Macromolecules, 1995, 28, 723-729.
Applied Physics Letters, 2006, 88, 093505: carbazole and triphenylamine derivatives for phosphorescent polymer LED.
Proc. Of SPIE, vol 6333 63330G-1: hole-transporting and emitting pendant polymers for OLED
Synthetic Metals, 2008, 158, 670-675: synthesis of new hole-transport molecular glass with pendant carbazoyl moieties.
J. Mat. Chem., 2008, 18, 4495-4509: in this paper, the authors provide a brief overview of pendant polymers incorporating various cross-linkable units.

Importantly, in addition to rendering the HTL material insoluble, the thermal cross-linking step results in the diffusion of a solution-deposited layer of transition metal oxide such as molybdenum trioxide into the HTL layer, and the formation of a doped ITO-HTL interface.

For the purpose of this invention, this doped ITO-HTL interface acts as a “Hole Injection Layer” (HIL) by ensuring low contact resistance.

In the case of other applications such as organic photovoltaic cells (OPVs) or organic thin film transistors (OTFTs) that do not require the solution-deposition of a second polymer layer, the HTL layer does not need to be thermally cross-linkable. However, even without cross-linkers, the annealing step is usually (but not always) still required, in order to thermally activate the p-doping of the HTL layer by interaction with the solution-deposited layer of transition metal oxide. However, where the HOMO of the semiconducting hole transport layer material is shallow, it is possible that doping can take place simply as a result of the drying step at much lower temperatures (100-150° C.) than the annealing step (200-300° C.).

After the thermally induced cross-linking of the HTL layer and creation of the p-doped ITO-HTL interface, the OLED pixel is completed by spin-coating of the light-emitting polymer (LEP) layer, followed by evaporation of the cathode and device encapsulation.

In one embodiment, we have found that it is preferred after the annealing step (d) to deposit a second solution of the same semiconducting hole transport layer material onto the annealed semiconducting hole transport layer. The deposited solution is then dried to form a non-annealed second layer of the same semiconducting hole transport layer material. We have found that devices having this “double stacked” geometry of, for example, a 30 nm annealed layer and a 30 nm non-annealed layer have high current levels at intermediate and high forward voltages, indicating efficient hole injection. The annealing in the first layer but not in the second layer means that there is p-doping in the transition metal oxide-semiconducting hole transport layer interface, and this is believed to improve rectifying behaviour as compared to the annealed single layer.

The present invention may be further understood by consideration of the following examples with reference to the following drawings.

### BRIEF DESCRIPTION OF THE FIGURES

FIG. 1 shows I-V characteristics of OLED pixels with different hole injection layers (HILs), including prior art HILs and a HIL produced according to the process of the present invention; and

FIG. 2 shows I-V characteristics for an annealed single layer device according to the present invention and a double layer stack device comprising both annealed and non-annealed layers according to the present invention.

### EXAMPLE 1

### Preparation of a Water-Based Molybdenum Trioxide Precursor Formulation

Molybdenum trioxide powder (obtained from Sigma Aldrich) was dispersed in deionised water (0.2% w/w). The dispersion was ultrasonicated for 1 hour, and then heated at 80° C. for 2 hours. The resulting mixture was then allowed to cool to room temperature and stored overnight on a roller. The mixture was then filtered through PVDF syringe disc filters (pore size 0.1 micron) to give the desired water-based molybdenum trioxide precursor formulation (“molybdic acid”).

### EXAMPLE 2

### Deposition of a Water-Based Molybdenum Trioxide Precursor Formulation on ITO

An OLED substrate comprising ITO contact patterns on glass was pre-cleaned by rinsing with organic solvents and deionised water. A short UV-ozone treatment (120 seconds) was then applied to render the substrate hydrophilic. After the UV-ozone treatment, the substrate was rinsed with deionised water, and blown dry with nitrogen gas.

A freshly filtered solution of molybdenum trioxide precursor in deionised water (prepared as described in Example 1 above) was spin-coated onto the pre-cleaned OLED substrate (1200 rpm, 60 seconds). After spin-coating the molybdenum trioxide precursor onto the substrate, the substrate was dried in air (120° C. for 10 minutes), and the precursor was then annealed under nitrogen (200° C. for 30 minutes in a glove box) to give the desired molybdenum oxide modified ITO substrate.

Using the molybdenum trioxide precursor solution of Example 1, and the deposition parameters of Example 2, the thickness of the resulting molybdenum trioxide deposit on ITO was typically less than 1 nm (AFM surface roughness data).

The work function of native ITO (approx. 5.0 eV) was found to increase to from 5.3-5.6 eV after treatment with the molybdenum trioxide precursor, depending on the process conditions.

### EXAMPLE 3

### Comparison of OLED Pixels Fabricated with Different HILs

After the “pre-Interlayer bake” was prepared in Example 2, a Hole Transport Layer must be spin-coated onto the molybdenum trioxide-modified ITO contacts. Possible HTL materials include “Interlayers” (ILs), pendant polymers and light-emitting polymers and conjugated host materials.

For OLED applications, an important pre-requisite is the provision of thermal cross-linkers in the (first) HTL layer. This allows the first HTL layer to be rendered insoluble by thermal annealing, prior to spin-coating a second LEP layer on top of the HTL layer, without re-dissolving the first HTL layer.

Importantly, in addition to rendering the HTL material insoluble, the thermal cross-linking step results in the diffusion of solution-deposited molybdenum trioxide into the HTL layer, and the formation of a doped ITO-HTL interface.

For the purpose of this invention, this doped ITO-HTL interface acts as a “hole injection layer” (HIL) by ensuring low contact resistance.

As noted previously, in the case of other applications such as organic photovoltaic cells OPVs or organic thin film transistors (OTFTs) that do not require the solution-deposition of a second polymer layer, the HTL layer does not need to be thermally cross-linkable. However, even without cross-linkers, the annealing step is usually required, in order to thermally activate the p-doping of the HTL layer by interaction with molybdenum trioxide, unless the HOMO of the HTL material is shallow in which case the drying step at lower temperature may be sufficient to create the desired p-doping of the HTL layer.

After the thermally induced cross-linking of the HTL layer and creation of the p-doped ITO-HTL interface, the OLED pixel was completed by spin-coating of the Light-Emitting Polymer (LEP) layer, followed by evaporation of the cathode and device encapsulation.

### Spin-coating of the Interlayer/HTL:

Interlayer 3 (see above) is dissolved in ortho-xylene (0.6 wt %)
Spin-coating at 1500 rpm/6 sec in glove box
Annealing temp/time: 200° C./15 min in glove box

### Spin-Coating of the LEP:

LEP 1 (see above) is dissolved in ortho-xylene (0.8 wt %)
Spin-coating at 1000 rpm/6 sec in glove box
Drying time 100° C./10 min in glove box

### Cathode Evaporation:

Thermal evaporation of 2 nm NaF+200 nm Al+100 nm Ag

The I-V characteristics of three working OLED pixels with different Hole Injection Layers (HILs) were compared in the following:

Device geometry: [ITO/HIL/22 nm Interlayer 3/70 nm LEP 1/2 nm NaF+200 nm Al+100 nm Ag]:

HIL(1): 35 nm polymeric HIL: PEDOT:PSS.

HIL(2): 5 nm thermally evaporated molybdenum trioxide.

HIL(3): Solution-deposited molybdenum trioxide (according to Examples 1 & 2 above).

### Results:

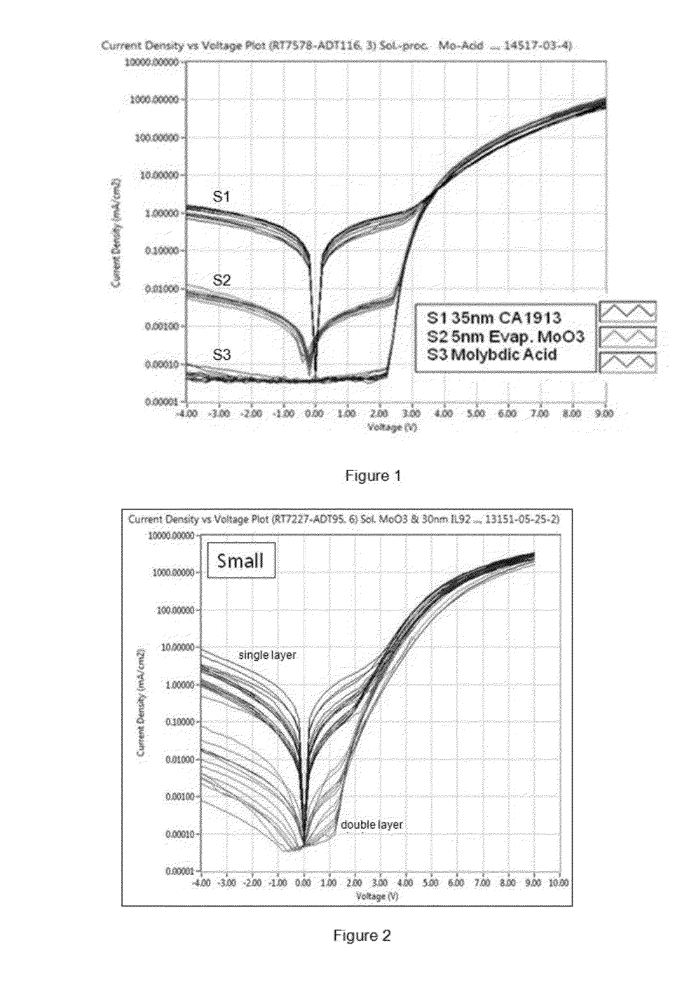

All HILs resulted in working devices with similar electroluminescence spectra (not shown here). However, the different HILs resulted in clear differences in the I-V characteristics at small forward and reverse bias voltages (see FIG. 1).
The polymeric HIL according to the prior art resulted in high current density levels at small forward and reverse bias voltages, due to its high conductivity and the resulting lateral leakage currents
The evaporated molybdenum trioxide according to the prior art resulted in intermediate current density levels, which could indicate lateral leakage currents due to n-doping as a result of oxygen deficiencies
Solution-deposited molybdenum trioxide resulted in ideal diode characteristics with extremely low current density levels at small forward and reverse bias voltages. The example illustrates that the elimination of lateral leakage currents is an advantage of solution-processed transition metal oxides such as molybdenum trioxide in accordance with the present invention as compared to evaporated molybdenum trioxide.
All three HILs result in very similar current levels at high forward voltages.

The amount of molybdenum trioxide diffusing into the bulk of the hole transport layer material, and the resulting degree of p-doping, as a function of temperature, generally depends on factors such as the solubility and chemical interactions of molybdenum trioxide in the polymer matrix, the HOMO-level of the polymer (i.e. the ionisation potential), and the glass transition temperature of the polymer.

### EXAMPLE 4

### Hole Injection into Interlayer 1 (IP 5.8 eV)

In the present example, we have demonstrated hole injection into deep HOMO HTL materials with solution-processed molybdenum trioxide, as illustrated for hole-only devices (HODs) with the deep-HOMO hole transfer layer Interlayer 1.

Device geometry: [ITO/Solution-processed molybdenum trioxide/60 nm Interlayer 1/200 nm Al+100 nm Ag] (HODs)

### Results:

Spin-coating of solution-processed molybdenum trioxide on the ITO surface resulted in a work function of approximately 5.4 eV [the IP of Interlayer 1 is approx. 5.8 eV]

Two separate devices were prepared. In the first, a single 60 nm layer of Interlayer 1 was deposited that was then dried and annealed. In the second, a first 30 nm layer of Interlayer 1 was deposited, dried and annealed before a second layer of Interlayer 1 was deposited and dried but not annealed to give an Interlayer 1 “double layer stack” (30 nm annealed Interlayer 1+30 nm non-annealed Interlayer 1).

Both the annealed Interlayer 1 single layer (60 nm) and the Interlayer 1 double layer stack (30 nm annealed Interlayer 1+30 nm non-annealed Interlayer 1) resulted in high current levels at intermediate and high forward voltages. This indicates efficient hole injection.

However, the double-layer stack gave improved rectifying behaviour as compared to the annealed single layer, with very low current levels at low forward and reverse voltages, thus improving efficiency.

1. A process for the preparation of a device comprising a transition metal oxide doped interface between an anode and a semiconducting hole transport layer, comprising the following steps:
(a) depositing a solution comprising a precursor for a metal oxide layer on said anode;
(b) drying and optionally annealing the deposited solution to form a solid layer precursor;
(c) depositing a solution of said semiconducting hole transport layer material onto the solid layer; and
(d) optionally annealing thermally the product of step (c) to give the desired device having transition metal oxide at the interface between said anode and said semiconducting hole transport layer.

2. The process according to claim 1, wherein the transition metal oxide is an oxide of molybdenum, tungsten, or vanadium.

3. The process according to claim 2, wherein the transition metal oxide is selected from the group consisting of molybdenum trioxide, tungsten trioxide and vanadium pentoxide.

4. The process according to claim 3, wherein the precursor for molybdenum trioxide is a dispersion or a dissolution of molybdenum trioxide, molybdic acid, ammonium molybdate, or phosphomolybdic acid in water.

5. The process according to claim 3, wherein the precursor for molybdenum trioxide is a dispersion or a dissolution of phosphomolybdic acid in a polar organic solvent.

6. The process according to claim 3, wherein the precursor for tungsten trioxide is a dispersion or a dissolution of tungsten trioxide, tungstic acid, ammonium tungstate, or phosphotungstic acid in water.

7. The process according to claim 3, wherein the precursor for tungsten trioxide is a dispersion or a dissolution of phosphotungstic acid in a polar organic solvent.

8. The process according to claim 3, wherein the precursor for vanadium pentoxide is a dispersion or a dissolution of vanadium (V) oxide, ammonium metavanadate, vanadium(V) oxytriethoxide, vanadium(V) oxytriisopropoxide, or vanadium(V) oxytripropoxide in water.

9. The process according to claim 3, wherein the precursor for vanadium pentoxide is a dispersion or a dissolution of vanadium(V) oxytriethoxide, vanadium(V) oxytriisopropoxide, or vanadium(V) oxytripropoxide in a polar organic solvent.

10. The process according to claim 1, wherein the depositing in step (a) is performed by spin-coating, dip-coating or doctor-blading.

11. The process according to claim 1, wherein the anode comprises indium tin oxide.

12. The process according to claim 1, further comprising pre-treating the anode surface with a hot mixture of concentrated hydrogen peroxide and concentrated ammonium hydroxide, by UV-ozone treatment or by oxygen plasma treatment before depositing the solution comprising a precursor for a metal oxide.

13. The process according to claim 1, wherein thermal cross-linkers are included in the semiconducting hole transport layer material deposited in step (c) and the product of step (c) is thermally annealed in step (d).

14. The process according to claim 13, further comprising deposition a solution of a semiconducting light emitting polymer material onto the annealed semiconducting hole transport layer and the deposited solution is then dried to form a solid semiconducting light emitting polymer layer.

15. The process according to claim 1, wherein the annealing step (d) is conducted at a temperature range of from 200 to 300° C.

16. The process according to claim 1, wherein the annealing step (d) is conducted, and further comprising after step (d), depositing a second solution of a semiconducting hole transport layer material, which may be the same or different from the first semiconducting hole transport layer material, onto the annealed semiconducting hole transport layer and the deposited solution is dried to form a non-annealed second layer of said semiconducting hole transport layer material.

17. A device comprising a transition metal oxide doped interface between an anode and a semiconducting hole transport layer, wherein said device is produced according to a process according to claim 1.

18. The device according to claim 17, wherein said device is selected from organic light emitting devices, organic photovoltaic cells and organic thin film transistors.
